(19) United States
(12) Patent Application Publication
(10) Pub. No.: US 2024/0421228 A1
(43) Pub. Date: Dec. 19, 2024

(54) NOISE TRANSISTOR

(71) Applicant: Taiwan Semiconductor Manufacturing Company, Ltd., Hsinchu (TW)

(72) Inventors: Che-Chun Lu, Tainan (TW); Yi-Hsing Chu, Tainan (TW); Chia-Yi Tseng, Tainan (TW)

(21) Appl. No.: 18/334,630

(22) Filed: Jun. 14, 2023

(51) Int. Cl. H01L 29/78; H01L 29/10; H01L 29/165; H01L 29/66

(52) U.S. Cl. CPC H01L 29/7848; H01L 29/1033; H01L 29/165; H01L 29/66545; H01L 29/66795; H01L 29/7851

(57) ABSTRACT

Noise semiconductor devices and methods of forming the same are provided. A semiconductor device according to the present disclosure includes a substrate, a fin structure over the substrate and extending lengthwise along a direction, the fin structure including a middle section sandwiched between a first end section and a second section along the direction, a gate structure wrapping over a channel region of the middle section, and a first source/drain feature and a second source/drain feature sandwiching the channel region of the middle section along the direction, The middle section includes a first semiconductor material and the first end section and the second end section include a second semiconductor material different from the first semiconductor material.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down has also been accompanied by increased complexity in design and manufacturing of devices incorporating these ICs, and, for these advances to be realized, similar developments in device fabrication are needed.

Neuromorphic computing has been developed to mimic information processing of a human brain, with a goal to better realize artificial intelligence. Contrary to the conventional wisdom to reduce noise, aspects of neuromorphic computing rely on random noise generation. Some noise generation devices have been developed. Although existing noise generation devices are adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart of a method for fabricating a semiconductor device on a workpiece, according to aspects of the present disclosure.

FIGS. 2-22 are fragmentary cross-sectional views or top views of the workpiece at various steps of the method of FIG. 1, according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Artificial intelligence (AI) is a field to enable machines to learn from experience, adjust new inputs, and perform human-like tasks. Conventional computers are able to store and process a large volume of data. However, everyday tasks pose problems that conventional computers are not ready to address. For example, recognition of objects, prediction of events in a dynamic natural environment involve processing disturbance and swift learning from a limited set of examples. For such everyday tasks, biological brains, such as human brains, are far more superior to conventional computers, especially in terms of energy consumption. Recognizing a human face takes a human being very little energy while doing so requires a conventional computer to identify characteristics of the human face and compare the characteristics to those of human faces in a vast database. To remedy the deficiencies of conventional computers, neuromorphic computing has emerged where AI tasks are carried by a dedicated brain-like computer.

To advance neuromorphic computing, computer scientists have turned to neuroscientists for help. Neuroscientists have long been able to record neural responses of an animal to a stimulus. They were surprised to find that the neural responses to repeated stimuli vary considerably. Spontaneous neuron activities were also observed even without any stimulus. These fluctuations and spontaneous activities were found to be random and once viewed as noise. Over the past decade or so, this view has changed dramatically. It is found that this noise, possibly generated in cerebral cortex, relates to arousal and stress, which heightens perception and sensory functions. These findings lead to a probabilistic approach based on a stochastic system. A stochastic system requires a source of completely random noise so as to enhance the response of the system to an input signal.

The present disclosure provides noise semiconductor devices and methods of forming the same. Instead of forming complicated semiconductor structures of various geometric shape, the present disclosure utilizes a wiggle fin structure formed by way of strain from a heterogeneous semiconductor structure. In an example, at least two regions of a second semiconductor material are formed in a substrate of a first semiconductor material such that a portion of the substrate is sandwiched between the at least two regions of the second semiconductor material. A fin structure is patterned from the two regions and the substrate to have a middle section sandwiched between two end sections. The middle section is formed of the first semiconductor material while the two end sections are formed of the second semiconductor material. When the first semiconductor material is silicon (Si) and the second semiconductor material is silicon germanium (SiGe), the two end sections exert a compressive stress on the middle section. Upon formation of the fin structure, the compressive stress may cause the middle section to deform to form a wiggle fin structure. After formation of a gate structure over the wiggle fin structure, a noise transistor is formed for generation of random noise. The processes to form the noise devices of the present disclosure are highly integratable with existing field effect transistor (FET) fabrication processes.

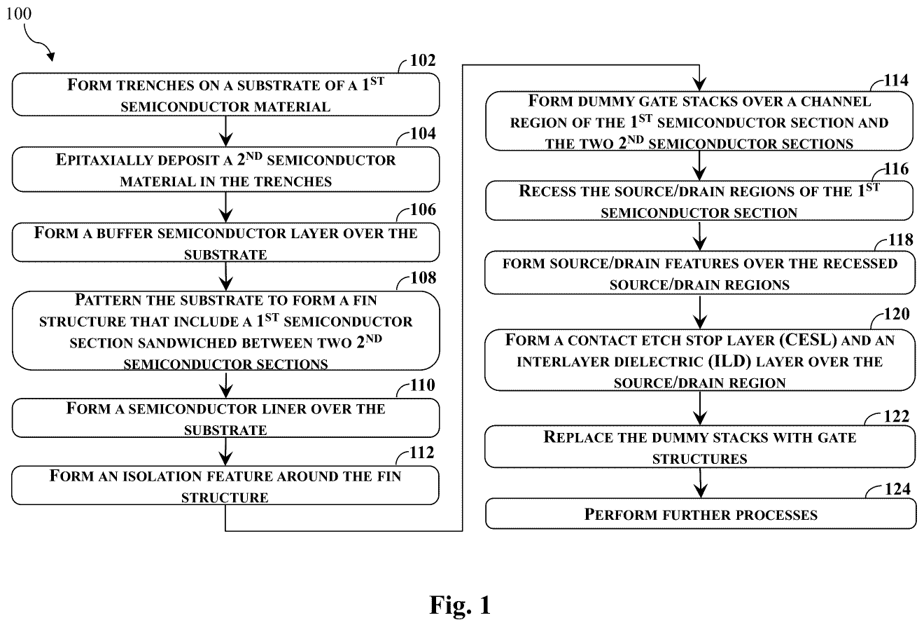

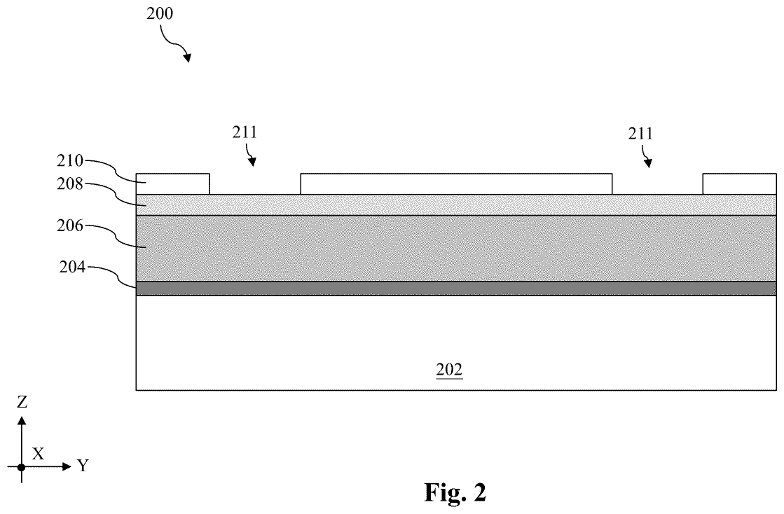

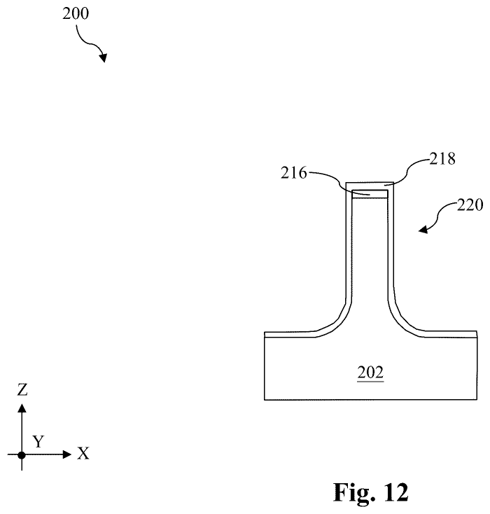

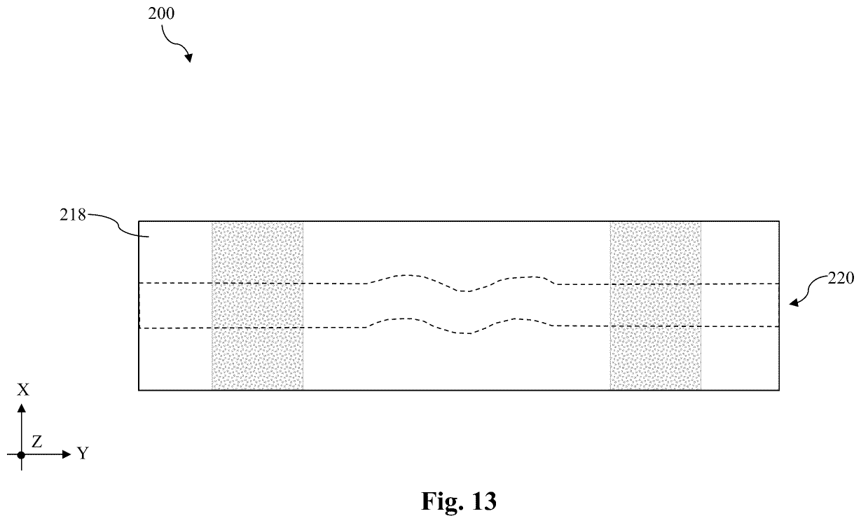

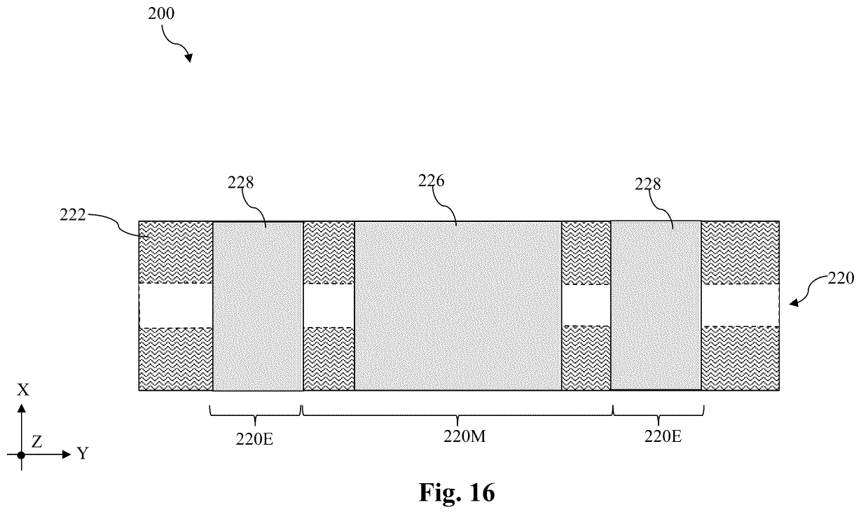

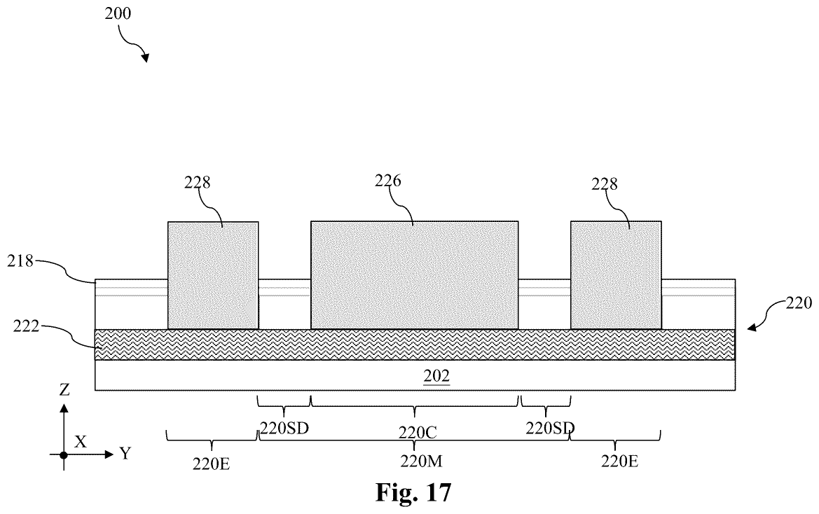

The various aspects of the present disclosure will now be described in more detail with reference to the figures. In that regard, FIG. 1 is a flowchart illustrating a method 100 of forming a self-powered image sensor according to embodiments of the present disclosure. Method 100 is merely an example and is not intended to limit the present disclosure to what is explicitly illustrated in method 100. Additional steps may be provided before, during and after the method 100, and some steps described can be replaced, eliminated, or moved around for additional embodiments of the method. Not all steps are described herein in detail for reasons of simplicity. Operations of method 100 are described below in conjunction with FIGS. 2-22, which are fragmentary cross-sectional views or top views of a workpiece 200 at various stages of fabrication. Because the workpiece 200 will be fabricated into a semiconductor device at the conclusion of the operations of method 100, the workpiece 200 may also be referred to as a semiconductor structure 200 as the context requires. Additionally, throughout the present application, like reference numerals denote like features, unless otherwise excepted. The X, Y and Z directions are used consistently in FIGS. 2-22 and are perpendicular to one another.

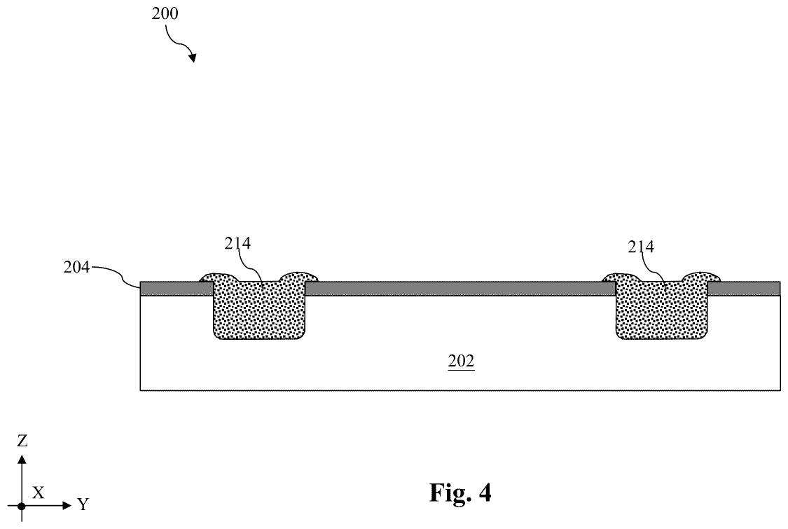

Referring to FIGS. 1, 2 and 3, method 100 includes a block 102 where trenches 212 are formed on a substrate 202. Referring to FIG. 2, the substrate 202 includes or is formed of a first semiconductor material different from a second semiconductor material 214 (to be described below in conjunction with block 104 and FIG. 4). The first semiconductor material and the second semiconductor material 214 are selected such that the second semiconductor material 214, when epitaxially grown on the first semiconductor material, exerts a compressive stress on the first semiconductor material due to lattice mismatch. In other words, a lattice constant of the second semiconductor material 214 is greater than a lattice constant of the first semiconductor material. In the depicted embodiments, the substrate 202 is formed of silicon (Si) while the second semiconductor material 214 is formed of silicon germanium (SiGe). In some instances, the second semiconductor material 214 has a germanium content between about 40% and about 95%. This range of germanium content is not trivial. When the germanium content in the second semiconductor material 214 is less than 40%, the second semiconductor material 214 may not exert sufficient stress on the substrate 202 to achieve the intended purposes of the present disclosure. When the germanium content in the second semiconductor material 214 is greater than 95%, the lattice mismatch between the first semiconductor material and the second semiconductor material may be too great. Such great lattice mismatch may result in too many voids or dislocation defects at interfaces between the first semiconductor material and the second semiconductor material 214, thereby preventing mechanical transfer of the compressive stress.

Reference is still made to FIG. 2. To carry out operations at block 104, a hard mask layer 204 is deposited over the substrate 202 and a photoresist is formed over the hard mask layer. In some embodiments, the hard mask layer 204 may include a dielectric material such as silicon oxide or silicon nitride. As will be described further below, the composition of the hard mask layer 204 is such that semiconductor material is less likely to be epitaxially formed on the hard mask layer 204. The photoresist shown in FIG. 2 is a multi-layer photoresist that includes a bottom layer 206 on the hard mask layer 204, a middle layer 208 on the bottom layer 206, and a photo-sensitive layer 210 on the middle layer 208. In some implementations, the bottom layer 206 may be a carbon-containing layer that includes carbon (C), hydrogen (H), and oxygen (O). The middle layer 208 may be silicon-containing layer that includes silicon (Si), hydrogen (H), and oxygen (O). The photo-sensitive layer 210 may include a polymer, a photo sensitizer, and a solvent. To form the trenches on the substrate 202, a photolithography process is performed to pattern the photo-sensitive layer 210. As shown in FIG. 2, two trench-like openings 211 are formed in the photo-sensitive layer 210. Each of the trench-like openings 211 is elongated along the X direction. The trench-like openings 211 expose portions of the middle layer 208.

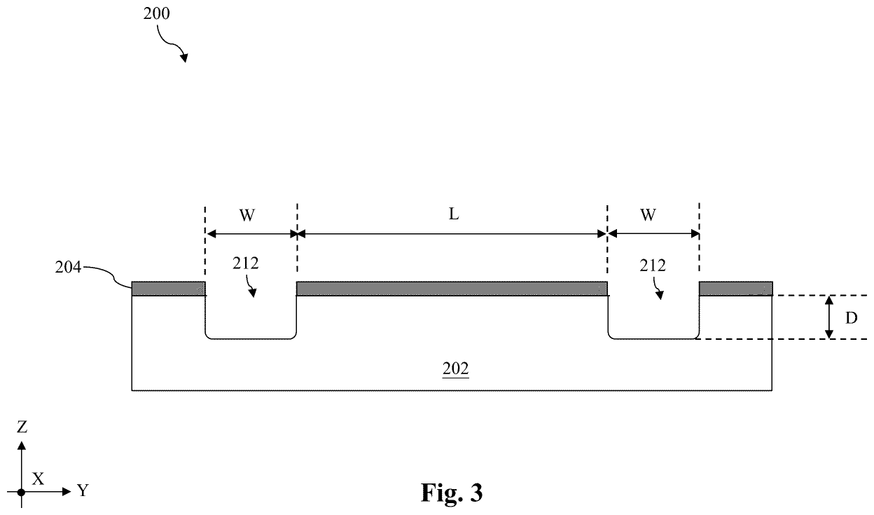

Referring to FIG. 3, the middle layer 208, the bottom layer 206, the hard mask layer 204, and the substrate 202 are etched using the patterned photo-sensitive layer 210 as an etch mask. In some embodiments, the etching process at block 102 may be a dry etch process. As shown in FIG. 3, the trench-like openings 211 in FIG. 2 are extended partially into the substrate 202 to form trenches 212. In embodiments represented in FIG. 3, the trenches 212 are spaced apart from one another by a distance L along the Y direction. Each of the trenches 212 has a width W along the Y direction. Along the Z direction, each of the trenches 212 extends a depth D into the substrate 202. In some instances, the distance L may be between 100 nm and about 2000 nm, the width W may be between about 50 nm and about 1000 nm, and the depth D may be between about 30 nm and about 200 nm. As will be described further below, these ranges are not trivial. The distance L relates to a channel length of a fin structure that is designed to have a wiggle or wavy shape due to compressive stress. When the distance L is smaller than 100 nm, the as-formed fin may not have room to form the desired wiggle shape. When the distance L is greater than 2000 μm, the as-formed fin may not be subject to sufficient strain to deform. The stress exerted by the second semiconductor material 214 in the trenches 212 may be dissipated along the Y direction. When the width W is smaller than 50 nm, the second semiconductor material 214 may not exert sufficient stress. When the width W is greater than 1000 nm, the second semiconductor material 214 may take up too much device region. The depth D of the trenches 212 has to do with epitaxial quality of the second semiconductor material 214 and a height of the fin. When the depth D is greater than 200 nm, the quality of the second semiconductor material 214 may suffer. When the depth D is smaller than 30 nm, the on-state current may not be sufficient and the amount of wiggle may not be enough to generate noise. After formation of the trenches 212, the bottom layer 206 and the middle layer 208 are removed by ashing or selective etching. As shown in FIG. 2, after the removal of the bottom layer 206 and the middle layer 208, the hard mask layer 204 remains on the substrate 202 and the trenches 212 also extend through the hard mask layer 204

Referring to FIGS. 1, 4 and 5, method 100 includes a block 104 where a second semiconductor material 214 is deposited over the trenches 212. With the trenches 212 defined in the hard mask layer 204 and the substrate 202, the second semiconductor material 214 is epitaxially and selectively grown over the trenches 212. As described above, the hard mask layer 204 is formed of a dielectric material that does not provide a suitable surface for epitaxial growth of semiconductor materials. In some embodiments, the second semiconductor material 214 includes silicon germanium (SiGe). In these embodiments, the second semiconductor material 214 is epitaxially grown on the exposed surfaces of the substrate 202 (in the trenches 212) at a temperature between about 550° C. to about 700° C. using a silicon containing gas (e.g., SiH₄, Si₂H₆, SiH₂Cl₂), a germanium containing gas (e.g., GeH₄ or Ge₂H₆), a combination thereof, as well as reactant/carrier gases such as H₂, N₂, or Ar, or a combination thereof. As shown in FIG. 4, while the second semiconductor material 214 is less likely to be deposited on the hard mask layer 204, an overgrowth of the second semiconductor material 214 may extend sideways to cover a portion of a top surface of the hard mask layer 204. It can be seen that the hard mask layer 204 functions as a deposition mask at block 104.

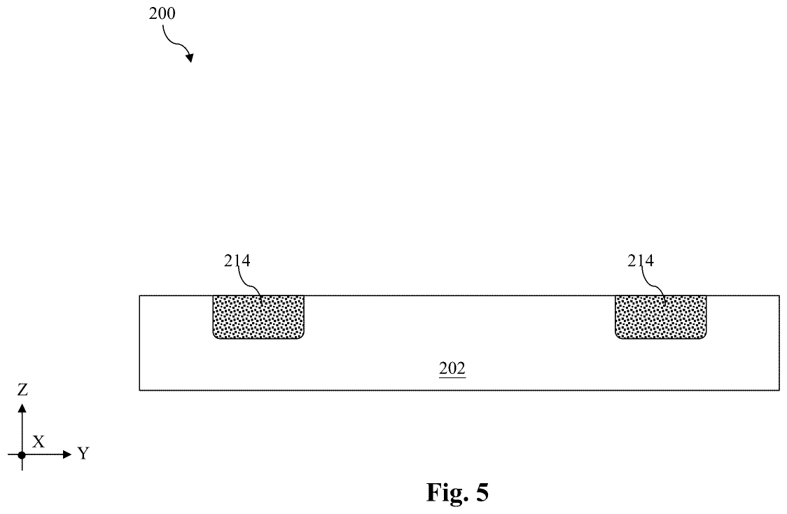

Referring to FIG. 5, after the deposition of the second semiconductor material 214 over the trenches 212, the workpiece 200 is planarized to remove the hard mask layer 204 and portions of the second semiconductor material 214 and the substrate 202, thereby forming a planar top surface. In some embodiments, the workpiece 200 is planarized using a chemical mechanical polishing (CMP) process.

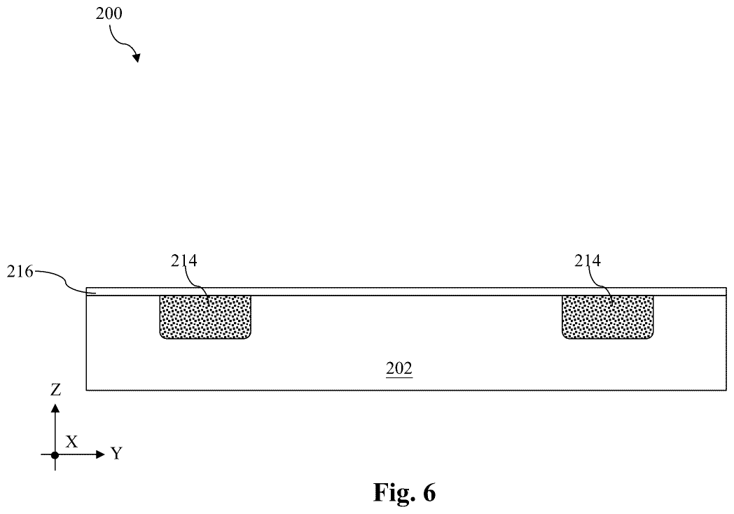

Referring to FIGS. 1 and 6, method 100 includes a block 106 where a buffer semiconductor layer 216 is deposited over the substrate 202. The buffer semiconductor layer 216 may include silicon (Si) to provide a more uniform top facing surfacer when the workpiece 200 is patterned to form a fin structure 220. Generally speaking, when the second semiconductor material 214 is formed of silicon germanium (SiGe) and the substrate 202 is formed of silicon (Si), an etching rate of the second semiconductor material 214 is greater than that of the substrate 202 in most anisotropic etching processes. To prevent uneven etching, the buffer semiconductor layer 216 is formed over the substrate 202, including over the second semiconductor material 214 to provide uniform etching characteristics in the subsequent anisotropic etching process. The buffer semiconductor layer 216 is epitaxially grown on the workpiece 200. In an example process, the buffer semiconductor layer 216 is epitaxially grown on the planar surface of the workpiece 200 using source gases silane (SiH₄), silicon tetrachloride (SiCl₄), trichlorosilane (TCS), dichlorosilane (SiH₂Cl₂ or DSC), or hydrogen (H₂). The deposition temperature for the buffer semiconductor layer 216 may be between about 700° C. and about 1250° C. In some embodiments, the buffer semiconductor layer 216 may be optionally subjected to an anneal process using radiation heating at temperature between about 800° C. and about 1050° C. to improve its quality.

Referring to FIGS. 1 and 7-10, method 100 includes a block 108 where the substrate 202 is patterned to form a fin structure 220 having a middle section 220M sandwiched between two end sections 220E along the Y direction. To form the fin structure 220, a fin-top hard mask layer (not explicitly shown in the figures) may be deposited over the buffer semiconductor layer 216. The fin-top hard mask layer may be a single layer or a multilayer. When the fin-top hard mask layer is a multilayer, it may include a first hard mask layer and a second hard mask layer on the first hard mask layer. The first hard mask layer and the second hard mask layer have different compositions. In some embodiments, the first hard mask layer is formed of silicon oxide and the second hard mask layer is formed of silicon nitride. In some implementations, a combination of deposition, lithography and/or etching processes are performed to define the fin structure 220. The etching process can include a dry etching process (for example, a reactive ion etching (RIE) process), a wet etching process, other suitable etching process, or combinations thereof.

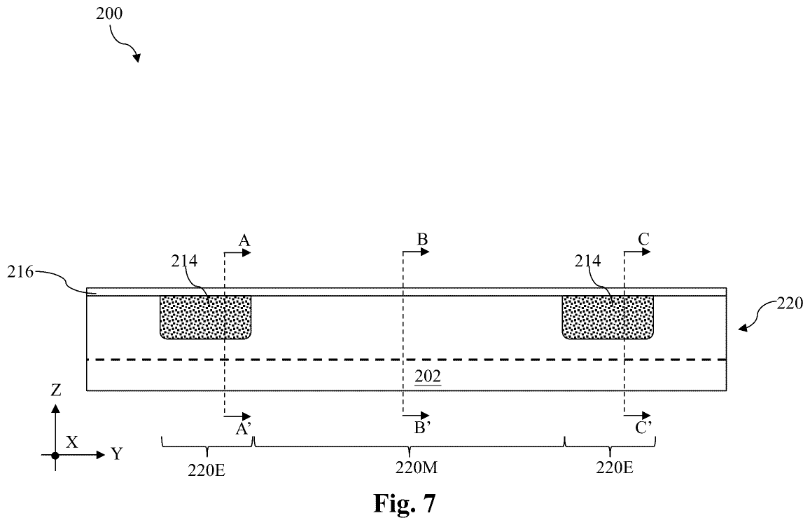

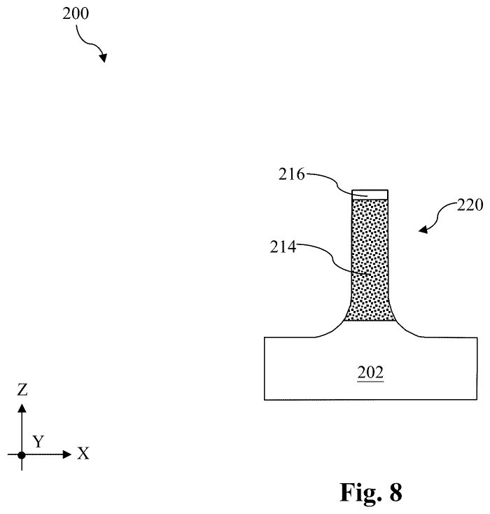

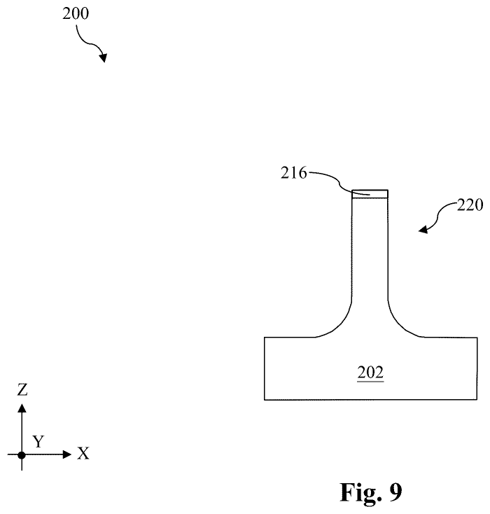

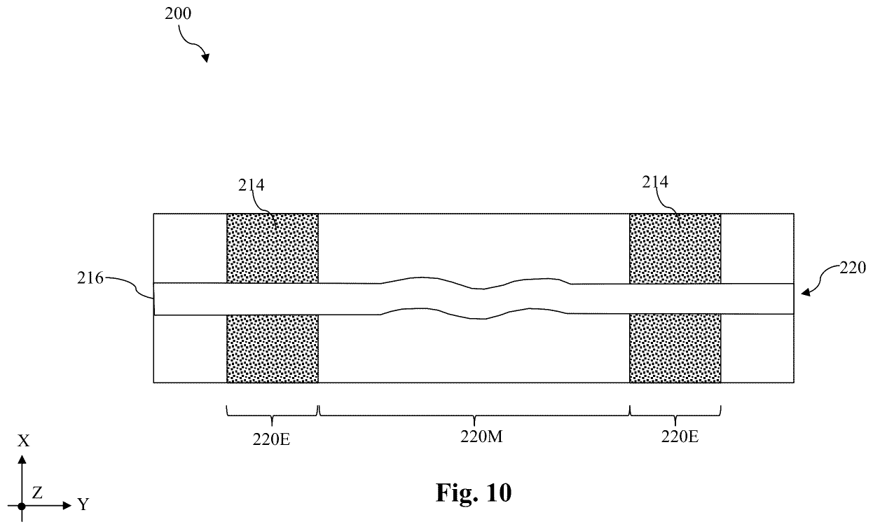

As shown in cross-sectional view in FIG. 7 and the top view in FIG. 10, the fin structure 220 including a middle section 220M and two end sections 220E. The middle section 220M is sandwiched between the two end sections 220E along the Y direction. Due to the formation of the second semiconductor material 214 in the trenches 212, the middle section 220M includes silicon (Si) as both the substrate 202 and the buffer semiconductor layer 216 are formed of silicon (Si). The two end sections 220E of the fin structure 220 may be largely formed of silicon germanium (SiGe) as the second semiconductor material 214 includes silicon germanium (SiGe) and the buffer semiconductor layer 216 is formed of silicon (Si). The fragmentary cross-sectional views along lines A-A′, B-B′ and C-C′ in FIG. 7 better illustrates the structures of the middle section 220M and the two end sections 220E. As shown in FIG. 7, line A-A′ cuts through the end section 220E on the left, line B-B′ cuts through the middle section 220M, and line C-C′ cuts through the end section 220E on the right. FIG. 8 illustrates a fragmentary cross-sectional view across either line A-A′ or line C-C′. FIG. 9 illustrates a fragmentary cross-sectional view across line B-B′. Referring to FIG. 8, each of the two end sections 220E includes a fin segment patterned from the second semiconductor material 214 and the overlying buffer semiconductor layer 216. Referring to FIG. 9, the middle section 220M includes fin segment patterned from the substrate 202 and the overlying buffer semiconductor layer 216.

Reference is now made to FIG. 10. As described above, the lattice mismatch between the first semiconductor material of the substrate 202 and the second semiconductor material 214 cause a compressive stress in the portion of the substrate 202 between the two semiconductor material 214. Before the formation of the fin structure 220 at block 108, the stress is not sufficient to deform the portion of the substrate 202 between the two filled trenches 212. However, as shown in FIG. 10, after the formation of the fin structure 220, the middle section 220M may yield to the compressive stress exerted by the two end sections 220E and manifest a deformation in the form of a wiggle. Depending on the length of the middle section 220M, which is directly related to the distance L between the trenches 212 shown in FIG. 3, the deformation may be mild or substantial. In general, a middle section 220M with a greater distance L may demonstrate more wiggle. As shown in FIG. 10, the middle section 220M may be characterized by a wiggle fin segment or a wavy fin segment. While the amount of wiggle is related to the distance L, variations in material uniformity, thermal history and process may make the amount of wiggle random and unpredictable. Because the amount of wiggle is directly related to noise, the unpredictable wiggle in the middle section 220M causes the resulting device to generate completely random noise. FIG. 10 also shows how the trenches 212 and the second semiconductor material 214 extends lengthwise along the X direction.

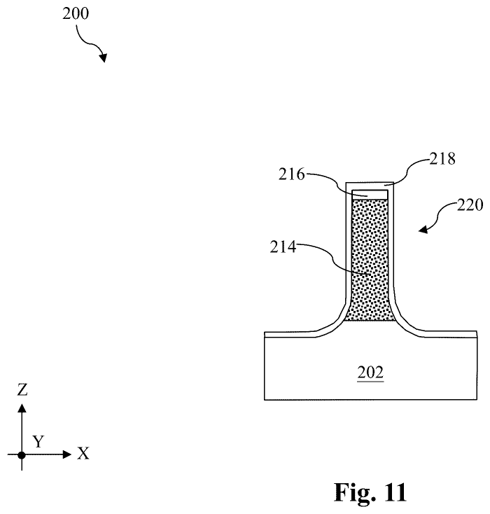

Referring to FIGS. 1 and 11-13, method 100 includes a block 110 where a semiconductor liner 218 is formed over the substrate 202, including over the fin structure 220. The semiconductor liner 218 serves to protect sidewalls of the second semiconductor material 214 in the end sections 220E in the following etching back processes. In some embodiments, the semiconductor liner 218 includes silicon (Si) and is deposited epitaxially on surfaces of the substrate 202 and the fin structure 220 using source gases such as silane (SiH₄), silicon tetrachloride (SiCl₄), trichlorosilane (TCS), or dichlorosilane (SiH₂Cl₂ or DSC) and a reactant gas such as hydrogen (H₂). In some instances, the semiconductor liner 218 may have a thickness between about 0.5 nm and about 5 nm. The deposition temperature for the semiconductor liner 218 may range from about 700° C. to about 1250° C. depending on the gases used. As shown in FIGS. 11-13, the semiconductor liner 218 is disposed over top surfaces and sidewalls of the fin structure 220 as well as a top surface of the substrate 202. It is noted that because the buffer semiconductor layer 216 over the fin structure 220 has not been removed, a portion of the semiconductor liner 218 is disposed directly the top surface of the buffer semiconductor layer 216. In other words, in the end sections 220E, a top portion of the semiconductor liner 218 is spaced apart from a top surface of the second semiconductor material 214 by the buffer semiconductor layer 216. In some embodiments, the semiconductor liner 218 may be optionally subjected to an anneal process using radiation heating at temperature between about 800° C. and about 1050° C. to improve its quality.

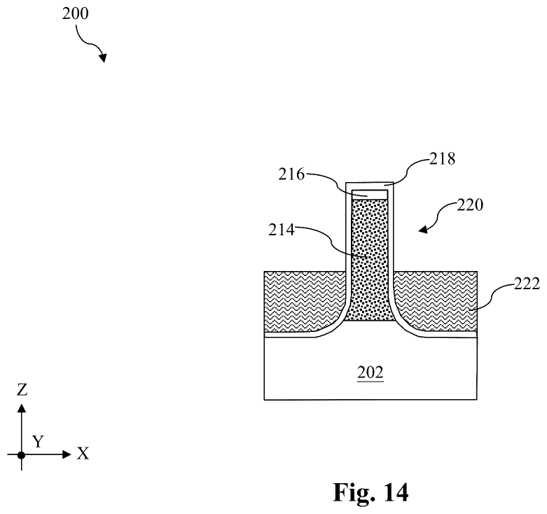

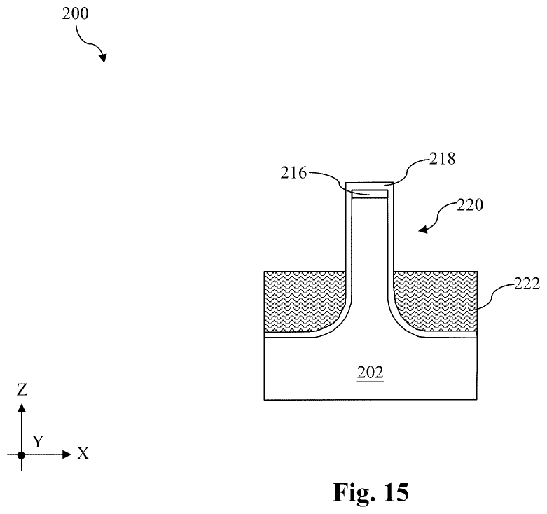

Referring to FIGS. 1, 14 and 15, method 100 includes a block 112 where an isolation feature 222 is formed around the fin structure 220. The isolation feature 222, as shown in FIGS. 14 and 15, isolate the fin structure 220 (including the middle section 220M and the end sections 220E) from another fin structure (omitted for simplicity). In an example process, a dielectric material is first blanketly deposited over the workpiece 200 to fill space between the fin structure 220 and another fin structure. The dielectric material may include silicon oxide, silicon oxynitride, other suitable isolation material, or combinations thereof and may be deposited by chemical vapor deposition (CVD) or a spin-on-glass (SOG) process. A planarization process, such as a CMP process, is then performed until the semiconductor liner 218 is exposed. The planarized dielectric material is then selectively etched back to form the isolation feature 222. It can be seen that the semiconductor liner 218 protects the second semiconductor material 214 in the end sections 220E during the etch back process. While not explicitly shown in FIGS. 14 and 15, a portion of the semiconductor liner 218 may be removed or etched away during the planarization and the etch back process.

Referring to FIGS. 1, 16 and 17, method 100 includes a block 114 where dummy gate stacks are formed over a channel region 220C of the middle section 220M and the two end sections 220E. In the depicted embodiments, a replacement gate process is adopted where dummy gate stacks are formed as a placeholder to undergo processes that are harmful to metal gate structures and the dummy gate stacks are replaced with functional metal gate structures. In the present disclosure, dummy gate stacks also serve to protect the second semiconductor material 214 in the fin structure 220. When dummy gate stacks are not formed to cover the second semiconductor material 214 in the end sections, the second semiconductor material 214 may suffer significant loss during the recessing of source/drain regions, resulting in stress loss. This is undesirable because the second semiconductor material 214 functions as a stressor, substantial loss of the stressor inevitably results in loss of stress. In the depicted embodiments, the dummy gate stacks formed at block 114 include a dummy gate stack 226 over a channel region 220C of the middle section 220M and two protective dummy gate stacks 228 over the entire length (along the Y direction) of the end sections 220E. The dummy gate stack 226 functions as a placeholder gate while the protective dummy gate stacks 228 cover and protect the second semiconductor material 214. The dummy gate stack 226 and the protective dummy gate stacks 228 may be formed simultaneously. In an example process, a dummy gate dielectric layer is first formed on the fin structure 220 using thermal oxidation, atomic layer deposition (ALD), or chemical vapor deposition (CVD) and a dummy electrode layer is formed on the dummy gate dielectric layer using CVD. In some embodiments, the dummy electrode layer includes polysilicon. After deposition of the dummy gate dielectric layer and the dummy electrode layer, they are patterned to form the dummy gate stack 226 and the protective dummy gate stacks 228.

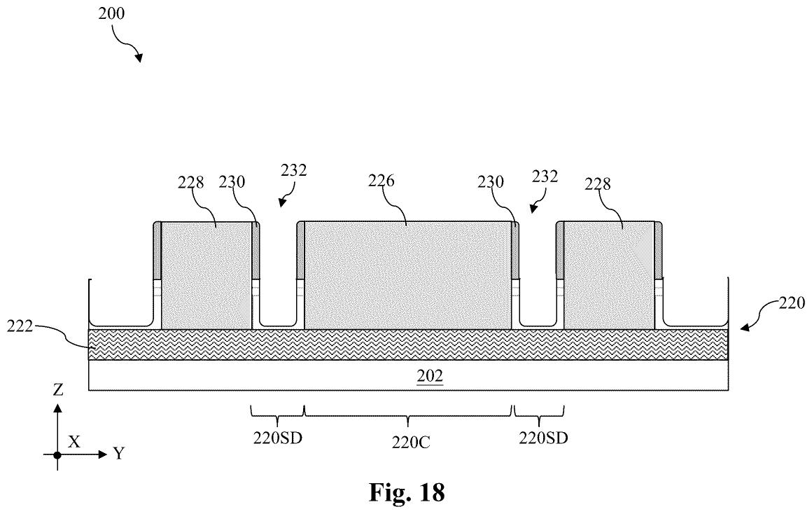

After the dummy gate stacks are formed, at least one gate spacer 230 (shown in FIG. 18) may be deposited over the dummy gate stacks (including the dummy gate stack 226 and the protective dummy gate stacks 228). The at least one gate spacer 230 may include silicon oxide, silicon nitride, silicon oxynitride, silicon carbonitride, or a combination thereof.

Referring to FIGS. 1 and 18, method 100 includes a block 116 where the source/drain regions 220SD of the middle section 220M are recessed. In some embodiments, the source/drain regions 220SD of the middle section 220M are anisotropically etched using a dry etch or a suitable etching process to form the source/drain recesses 232. For example, the dry etch process may implement oxygen (O₂), an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 18, after the formation of the source/drain recesses 232, the at least one gate spacer 230 may remain disposed along sidewalls of the dummy gate stack 226 and the protective dummy gate stacks 228.

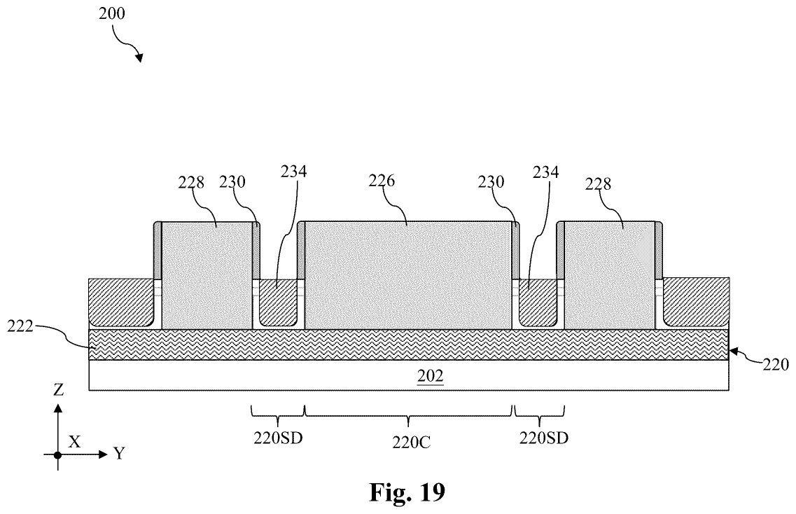

Referring to FIGS. 1 and 19, method 100 includes a block 118 where source/drain features 234 are formed over the source/drain regions 220SD. At block 118, source/drain features 234 are formed over the source/drain recess 232 in the source/drain regions 220SD using an epitaxy process. The epitaxy process may implement CVD deposition techniques (for example, vapor-phase epitaxy (VPE), ultra-high vacuum CVD (UHV-CVD), LPCVD, and/or PECVD), molecular beam epitaxy (MBE), other suitable selective epitaxial growth (SEG) processes, or combinations thereof. The source/drain features 234 may be n-type or p-type. When the source/drain features 234 are p-type, they include silicon germanium (SiGe) and a p-type dopants, such boron (B). When the source/drain features 234 are n-type, they include silicon (Si) and an n-type dopants, such as phosphorus (P). In the depicted embodiment, the source/drain features 234 are n-type. After the formation of the source/drain features 234, an annealing process may be performed to activate dopants in source/drain features 234.

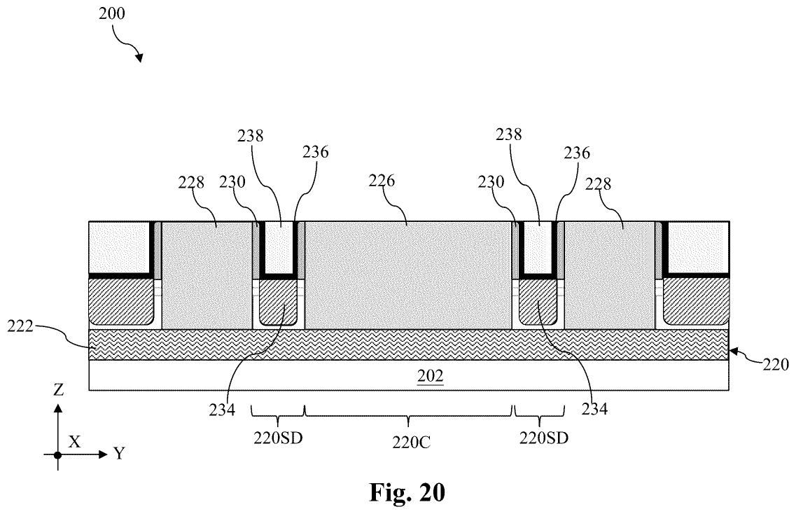

Referring to FIGS. 1 and 20, method 100 includes a block 120 where a contact etch stop layer (CESL) 236 and an interlayer dielectric (ILD) layer 380 are formed over the source/drain features 234. As shown in FIG. 20, the CESL 236 is formed on the source/drain features 234 and the ILD layer 238 is formed on the CESL 236. The ILD layer 238 is spaced apart from the at least one gate spacer 230 by the CESL 236. In some embodiments, the CESL 236 includes silicon nitride, silicon oxynitride, and/or other materials known in the art. The CESL 236 may be deposited using ALD, plasma-enhanced chemical vapor deposition (PECVD) process and/or other suitable deposition processes. The ILD layer 38 is then deposited over the CESL 236. In some embodiments, the ILD layer 238 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 238 may be deposited by a spin-on process, or other suitable deposition technique. In some embodiments, after formation of the ILD layer 238, the workpiece 200 may be annealed to improve integrity of the ILD layer 238. Reference is still made to FIG. 20. After the deposition of the ILD layer 238, the workpiece 200 is planarized to expose the dummy gate stack 226 and the protective dummy gate stacks 228. At end conclusion of the planarization process, top surfaces of the ILD layer 238, the CESL 236, the dummy gate stack 226, and the protective dummy gate stacks 228 are coplanar.

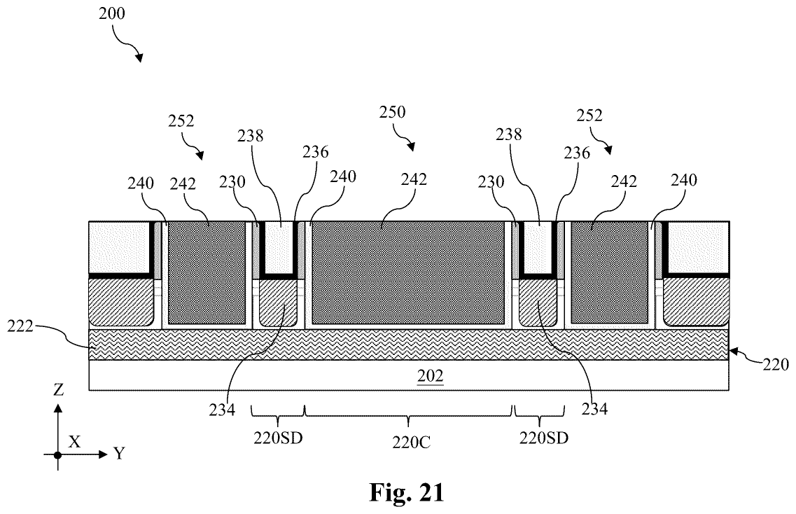

Referring to FIGS. 1 and 21, method 100 includes a block 122 where the dummy gate stacks are replaced with gate structures. At block 122, gate replacement operations are performed to replace the dummy gate stacks (including the dummy gate stack 226 and the protective dummy gate stacks 228) with metal gate structures (including a first gate structure 250 and two second gate structures 252). First, the dummy gate stacks (including the dummy gate stack 226 and the protective dummy gate stacks 228) are removed to form gate trenches. The end sections 220E and channel region 220C of the middle section 220M are exposed in the gate trenches. Then, the first gate structure 250 and two second gate structures 252 are deposited in the gate trenches. In some embodiments, each of the first gate structure 250 and the second gate structures 252 may include a gate dielectric layer 240 and a gate electrode layer 242 over the gate dielectric layer 240. In some implementations, the gate dielectric layer 240 may include a silicon oxide interfacial layer and a high-k dielectric layer. The high-k dielectric layer is formed of a dielectric material having a high dielectric constant, for example, greater than a dielectric constant of silicon oxide (k≈3.9). Exemplary high-k dielectric materials include hafnium, aluminum, zirconium, lanthanum, tantalum, titanium, yttrium, oxygen, nitrogen, other suitable constituent, or combinations thereof. In some implementations, the high-k dielectric layer may include, for example, HfO₂, HfSiO, HfSiON, HfTaO, HfTiO, HfZrO, ZrO₂, Al₂O₃, HfO₂—Al₂O₃, TiO₂, Ta₂O₅, La₂O₃, Y₂O₃, other suitable high-k dielectric material, or combinations thereof. The gate electrode layer 242 includes an electrically conductive material. In some implementations, the gate electrode layer 242 includes multiple layers, such as one or more capping layers, work function layers, glue/barrier layers, and/or metal fill (or bulk) layers. A capping layer can include a material that prevents or eliminates diffusion and/or reaction of constituents between the gate dielectric layer 240 and other layers of the gate electrode layer 242. In some implementations, the capping layer includes a metal and nitrogen, such as titanium nitride (TiN), tantalum nitride (TaN), tungsten nitride (W₂N), titanium silicon nitride (TiSiN), tantalum silicon nitride (TaSiN), or combinations thereof. A work function layer includes a conductive material tuned to have a desired work function (such as an n-type work function or a p-type work function), such as n-type work function materials and/or p-type work function materials. P-type work function materials include TiN, TaN, Ru, Mo, Al, WN, ZrSi₂, MoSi₂, TaSi₂, NiSi₂, WN, other p-type work function material, or combinations thereof. N-type work function materials include Ti, Al, Ag, Mn, Zr, TiAl, TiAlC, TaC, TaCN, TaSiN, TaAl, TaAlC, TiAlN, other n-type work function material, or combinations thereof. A glue/barrier layer can include a material that promotes adhesion between adjacent layers, such as the work function layer and the metal fill layer, and/or a material that blocks and/or reduces diffusion between gate layers, such as such as the work function layer and the metal fill layer. For example, the glue/barrier layer includes metal (for example, W, Al. Ta, Ti, Ni, Cu, Co, other suitable metal, or combinations thereof), metal oxides, metal nitrides (for example, TiN), or combinations thereof. A metal fill layer can include a suitable conductive material, such as W or Cu. In the depicted embodiments, the gate dielectric layer 240 includes silicon oxide and hafnium oxide and the gate electrode layer 242 includes TIN, TiAl, and tungsten. As shown in FIG. 21, a planarization, such as a CMP process, is performed to remove excess materials.

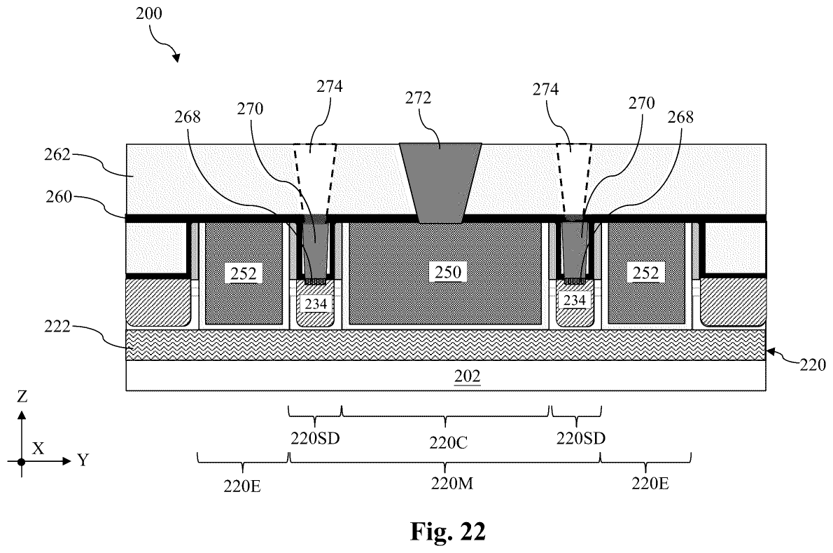

Referring to FIGS. 1 and 22, method 100 includes a block 124 where further processes are performed. Such further processes may include, for example, formation of source/drain contacts 270, deposition of an etch stop layer (ESL) 260, deposition of a top interlayer dielectric (ILD) layer 262, formation of a gate contact via 272, and formation of source/drain contact vias 274. In some embodiments, each of the source/drain contact 270 extends through the CESL 236 and the ILD layer 238 (shown in FIG. 21) and contacts the source/drain feature 234 by way of a silicide feature 268. In some embodiments, the source/drain contact 270 may include ruthenium (Ru), cobalt (Co), nickel (Ni), or copper (Cu). The silicide feature 268 may include titanium silicide. While not explicitly shown in the figures, each of the source/drain contacts 270 is spaced apart from the ILD layer 238 by a barrier layer, which may include titanium nitride (TiN) or tantalum nitride (TaN). The ESL 260 may have a composition similar to that of the CESL 236 and the top ILD layer 262 may have a composition similar to that of the ILD layer 238. As shown in FIG. 22, the gate contact via 272 extends through the ESL 260 and the top ILD layer 262 to contact the first gate structure 250. The source/drain contact vias 274 extend through the ESL 260 and the top ILD layer 262 to contact the source/drain contacts 270. In some instances, the gate contact via 272 and the source/drain contact vias 274 may include titanium nitride (TiN), tungsten (W), ruthenium (Ru), cobalt (Co), nickel (Ni), or copper (Cu). The source/drain contact vias 274 are shown in dotted lines because they are out-of-plane with the gate contact via 272 or the first gate structure 250. In some embodiments represented in FIG. 22, the second gate structures 252 are not electrically connected to any conductive contacts and are electrically floating.

The present disclosure provides noise semiconductor devices and methods of forming the same. In one aspect, a semiconductor device is provided. The semiconductor device includes a substrate, a fin structure over the substrate and extending lengthwise along a direction, the fin structure including a middle section sandwiched between a first end section and a second end section along the direction, a gate structure wrapping over a channel region of the middle section, and a first source/drain feature and a second source/drain feature sandwiching the channel region of the middle section along the direction. The middle section includes a first semiconductor material and the first end section and the second end section include a second semiconductor material different from the first semiconductor material.

In some embodiments, the first end section and the second end section exert a compressive stress on the middle section along the direction. In some implementations, the first semiconductor material includes silicon (Si) and the second semiconductor material includes silicon germanium (SiGe). In some embodiments, the second semiconductor material includes a germanium content between about 40% and about 95%. In some instances, the semiconductor device further includes a buffer semiconductor layer disposed on top surfaces of the channel region of the middle section, the first end section and the second end section. In some embodiments, the buffer semiconductor layer includes silicon (Si). In some implementations, the semiconductor device further includes a semiconductor liner disposed over the buffer semiconductor layer and sidewalls of the channel region of the middle section, the first end section and the second end section. In some instances, the semiconductor liner includes silicon (Si). In some embodiments, the channel region of the middle section is wavy in a top view.

In another aspect, a semiconductor structure is provided. The semiconductor structure includes a substrate of a first semiconductor material, a fin structure over the substrate and including a middle section formed of the first semiconductor material, and a first end section and a second end section sandwiching the middle section along a direction and formed of a second semiconductor material different from the first semiconductor material, a first gate structure wrapping over a channel region of the middle section, a second gate structure wrapping over the first end section, a third gate structure wrapping over the second end section, and a first source/drain feature and a second source/drain feature sandwiching the channel region of the middle section along the direction.

In some embodiments, the first semiconductor material includes silicon (Si) and the second semiconductor material includes silicon germanium (SiGe). In some implementations, the first gate structure includes a first gate dielectric layer wrapping over the channel region of the middle section and a first gate electrode wrapping over the first gate dielectric layer, the second gate structure includes a second gate dielectric layer wrapping over the first end section and a second gate electrode wrapping over the second gate dielectric layer, and the third gate structure includes a third gate dielectric layer wrapping over the second end section and a third gate electrode wrapping over the third gate dielectric layer. A composition of the first gate dielectric layer, a composition of the second gate dielectric layer, and a composition of the third gate dielectric layer are the same. A composition of the first gate electrode, a composition of the second gate electrode, and a composition of the third gate electrode are the same. In some embodiments, the first gate dielectric layer, the second gate dielectric layer, and the third gate dielectric layer include silicon oxide, hafnium oxide, zirconium oxide, aluminum oxide, titanium oxide, tantalum oxide, lanthanum oxide, yttrium oxide, or a combination thereof and the first gate electrode, the second gate electrode, and the third gate electrode include titanium nitride, titanium aluminum, titanium aluminum carbide, titanium aluminum nitride, or tungsten. In some embodiments, the first source/drain feature is in contact with the first end section and the second source/drain feature is in contact with the second end section. In some embodiments, the first end section and the second end section exert a compressive stress on the middle section along the direction.

In still another embodiment, a method is provided. The method includes depositing a hard mask layer on a substrate of a first semiconductor material, forming a first trench and a second trench in the substrate and the hard mask layer, the first trench and the second trench extending lengthwise along a first direction, epitaxially depositing a second semiconductor material over the first trench and the second trench, patterning the substrate to form a fin structure extending lengthwise along a second direction perpendicular to the first direction to have a middle section formed of the first semiconductor material and a first end section and a second end section formed of the second semiconductor material, forming first dummy gate stack over a channel region of the middle section, a second dummy gate stack over the first end section, and a third dummy gate stack over the second end section, recessing source/drain regions of the middle section to form two source/drain recesses adjacent ends of the channel region, forming source/drain features in the two source/drain recesses, and replacing the first dummy gate stack, the second dummy gate stack, and a third dummy gate stack with a first gate structure, a second gate structure, and a third gate structure, respectively. The second semiconductor material is different from the first semiconductor material.

In some embodiments, the first semiconductor material includes silicon (Si) and the second semiconductor material includes silicon germanium (SiGe). In some implementations, the method further includes after the epitaxially depositing, planarizing the substrate and the second semiconductor material until the hard mask layer is removed. In some embodiments, the method further includes after the planarizing, depositing a buffer semiconductor layer over the substrate and the second semiconductor material. In some instances, the method further includes after the patterning of the substrate to form the fin structure, depositing a semiconductor liner over the buffer semiconductor layer and the fin structure.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a substrate;
a fin structure over the substrate and extending lengthwise along a direction, the fin structure including a middle section sandwiched between a first end section and a second end section along the direction;
a gate structure wrapping over a channel region of the middle section; and
a first source/drain feature and a second source/drain feature sandwiching the channel region of the middle section along the direction,
wherein the middle section comprises a first semiconductor material and the first end section and the second end section comprise a second semiconductor material different from the first semiconductor material.

2. The semiconductor device of claim 1, wherein the first end section and the second end section exert a compressive stress on the middle section along the direction.

3. The semiconductor device of claim 1,
wherein the first semiconductor material comprises silicon (Si),
wherein the second semiconductor material comprises silicon germanium (SiGe).

4. The semiconductor device of claim 3, where the second semiconductor material comprises a germanium content between about 40% and about 95%.

5. The semiconductor device of claim 1, further comprising:
a buffer semiconductor layer disposed on top surfaces of the channel region of the middle section, the first end section and the second end section.

6. The semiconductor device of claim 5, wherein the buffer semiconductor layer comprises silicon (Si).

7. The semiconductor device of claim 5, further comprising:
a semiconductor liner disposed over the buffer semiconductor layer and sidewalls of the channel region of the middle section, the first end section and the second end section.

8. The semiconductor device of claim 7, wherein the semiconductor liner comprises silicon (Si).

9. The semiconductor device of claim 1, wherein the channel region of the middle section is wavy in a top view.

10. A semiconductor structure, comprising:
a substrate of a first semiconductor material;
a fin structure over the substrate, the fin structure comprising:
a middle section formed of the first semiconductor material, and
a first end section and a second end section sandwiching the middle section along a direction and formed of a second semiconductor material different from the first semiconductor material;
a first gate structure wrapping over a channel region of the middle section;
a second gate structure wrapping over the first end section;
a third gate structure wrapping over the second end section; and
a first source/drain feature and a second source/drain feature sandwiching the channel region of the middle section along the direction.

11. The semiconductor structure of claim 10,
wherein the first semiconductor material comprises silicon (Si),
wherein the second semiconductor material comprises silicon germanium (SiGe).

12. The semiconductor structure of claim 10,
wherein the first gate structure comprises a first gate dielectric layer wrapping over the channel region of the middle section and a first gate electrode wrapping over the first gate dielectric layer,
wherein the second gate structure comprises a second gate dielectric layer wrapping over the first end section and a second gate electrode wrapping over the second gate dielectric layer,
wherein the third gate structure comprises a third gate dielectric layer wrapping over the second end section and a third gate electrode wrapping over the third gate dielectric layer,
wherein a composition of the first gate dielectric layer, a composition of the second gate dielectric layer, and a composition of the third gate dielectric layer are the same,
wherein a composition of the first gate electrode, a composition of the second gate electrode, and a composition of the third gate electrode are the same.

13. The semiconductor structure of claim 12,
wherein the first gate dielectric layer, the second gate dielectric layer, and the third gate dielectric layer comprise silicon oxide, hafnium oxide, zirconium oxide, aluminum oxide, titanium oxide, tantalum oxide, lanthanum oxide, yttrium oxide, or a combination thereof,
wherein the first gate electrode, the second gate electrode, and the third gate electrode comprise titanium nitride, titanium aluminum, titanium aluminum carbide, titanium aluminum nitride, or tungsten.

14. The semiconductor structure of claim 10,
wherein the first source/drain feature is in contact with the first end section,
wherein the second source/drain feature is in contact with the second end section.

15. The semiconductor structure of claim 10, wherein the first end section and the second end section exert a compressive stress on the middle section along the direction.

16. A method, comprising:
depositing a hard mask layer on a substrate of a first semiconductor material;
forming a first trench and a second trench in the substrate and the hard mask layer, the first trench and the second trench extending lengthwise along a first direction;
epitaxially depositing a second semiconductor material over the first trench and the second trench;
patterning the substrate to form a fin structure extending lengthwise along a second direction perpendicular to the first direction to have a middle section formed of the first semiconductor material and a first end section and a second end section formed of the second semiconductor material;
forming first dummy gate stack over a channel region of the middle section, a second dummy gate stack over the first end section, and a third dummy gate stack over the second end section;
recessing source/drain regions of the middle section to form two source/drain recesses adjacent ends of the channel region;
forming source/drain features in the two source/drain recesses; and
replacing the first dummy gate stack, the second dummy gate stack, and a third dummy gate stack with a first gate structure, a second gate structure, and a third gate structure, respectively,
wherein the second semiconductor material is different from the first semiconductor material.

17. The method of claim 16,
wherein the first semiconductor material comprises silicon (Si),
wherein the second semiconductor material comprises silicon germanium (SiGe).

18. The method of claim 16, further comprising:
after the epitaxially depositing, planarizing the substrate and the second semiconductor material until the hard mask layer is removed.

19. The method of claim 18, further comprising:
after the planarizing, depositing a buffer semiconductor layer over the substrate and the second semiconductor material.

20. The method of claim 19, further comprising:
after the patterning of the substrate to form the fin structure, depositing a semiconductor liner over the buffer semiconductor layer and the fin structure.
